(19) United States
(12) Patent Application Publication
(10) Pub. No.: US 2024/0240871 A1
(43) Pub. Date: Jul. 18, 2024

(54) IMMERSION COOLING SYSTEM AND CONDENSATION DEHUMIDIFICATION DEVICE THEREOF

(71) Applicant: Wiwynn Corporation, New Taipei City (TW)

(72) Inventors: Hsien-Chieh Hsieh, New Taipei City (TW); Tsung-Han Li, New Taipei City (TW)

(21) Appl. No.: 18/527,480

(22) Filed: Dec. 4, 2023

(30) Foreign Application Priority Data
Jan. 18, 2023 (TW) 112102469

(51) Int. Cl. F28D 15/02; F28D 15/06

(52) U.S. Cl. CPC F28D 15/0266; F28D 15/06

(57) ABSTRACT

An immersion cooling system includes a work tank, a pump, a first pipeline, a condensation dehumidification device, a second pipeline, and a control system. The work tank includes a vapor section and a humidity sensor for sensing a humidity of the vapor section. The first pipeline includes a first valve. The vapor section and the pump are selectively in communication with each other or not when the first valve is actuated. The condensation dehumidification device has a first end and a second end, where the first end is in communication with the pump. The second pipeline includes a second valve. The condensation dehumidification device and the tank are selectively in communication with each other or not when the second valve is actuated. When the humidity is greater than a preset humidity, the control system controls the first valve to communicate the vapor section and the pump and activates the pump.

### CROSS-REFERENCE TO RELATED APPLICATION

This non-provisional application claims priority under 35 U.S.C. § 119(a) to U.S. patent application Ser. No. 11/210,2469 filed in Taiwan, R.O.C. on Jan. 18, 2023, and the entire contents of which are hereby incorporated by reference.

### BACKGROUND

### Technical Field

The instant disclosure relates to an immersion cooling system and a condensation dehumidification device thereof, particularly an immersion cooling system having a condensation dehumidification device.

### Related Art

In the immersion cooling system known to the inventor, component(s) to be cooled is usually placed in the working fluid. Hence, through the heat exchange between the working fluid and the component(s) to be cooled, the working fluid is further transformed from a liquid-phase fluid into a vapor-phase fluid, which may also contain moisture.

### SUMMARY

In view of this, according to some embodiments, an immersion cooling system having a condensation dehumidification device is provided, wherein the immersion cooling system comprises a work tank, a pump, a first pipeline, the condensation dehumidification device, a second pipeline, and a control system. The work tank comprises a vapor section and a work tank humidity sensor for sensing a humidity of the vapor section. The pump has an inlet and an outlet. The vapor section and the inlet are in communication with each other through the first pipeline. The first pipeline comprises a first valve, wherein the vapor section and the pump are selectively in communication with each other or not in communication with each other in response to that the first valve is actuated. The condensation dehumidification device has a first end and a second end, wherein the first end is in communication with the outlet. The second end of the condensation dehumidification device and the work tank are in communication with each other through the second pipeline. The second pipeline comprises a second valve, wherein the condensation dehumidification device and the work tank are selectively in communication with each other or not in communication with each other in response to that the second valve is actuated. The control system is for controlling the first valve to be in communication with the vapor section and the pump and actuating the pump in response to that the humidity of the vapor section is greater than a preset humidity.

In addition, according to some embodiments, a condensation dehumidification device for an immersion cooling system is provided, wherein the condensation dehumidification device has a first end and a second end. The first end of the condensation dehumidification device is adapted to be selectively in communication with or not in communication with a vapor section of the immersion cooling system. The second end of the condensation dehumidification device is adapted to be selectively in communication with the immersion cooling system or not in communication with the immersion cooling system. The condensation dehumidification device comprises a dehumidification portion and a condensation portion, wherein a position of the dehumidification portion is higher than a position of the first end, and a position of the condensation portion is lower than the position of the first end and higher than a position of the second end.

### BRIEF DESCRIPTION OF THE DRAWINGS

FIG. 1 illustrates a schematic perspective view of an immersion cooling system according to some embodiments;

FIG. 2 illustrates a schematic block diagram of a control system of the immersion cooling system shown in FIG. 1;

FIG. 3A illustrates a schematic working diagram in a first view (i.e., the YZ plane) of a condensation dehumidification device of the immersion cooling system shown in FIG. 1;

FIG. 3B illustrates a schematic working diagram in the first view (i.e., the YZ plane) of the condensation dehumidification device of the immersion cooling system shown in FIG. 1;

FIG. 4A illustrates a schematic working diagram in a second view (i.e., the XY plane) of the condensation dehumidification device of the immersion cooling system shown in FIG. 1;

FIG. 4B illustrates a schematic working diagram in a second view (i.e., the XY plane) of the condensation dehumidification device of the immersion cooling system shown in FIG. 1; and

FIG. 5 illustrates a perspective view of an immersion cooling system according to some embodiments.

### DETAILED DESCRIPTION

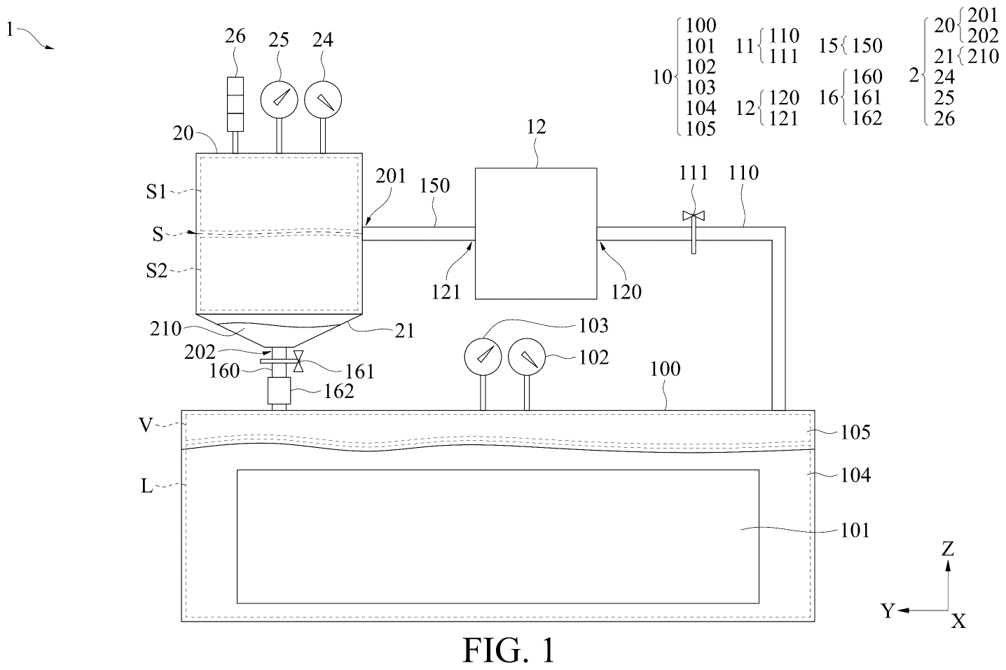

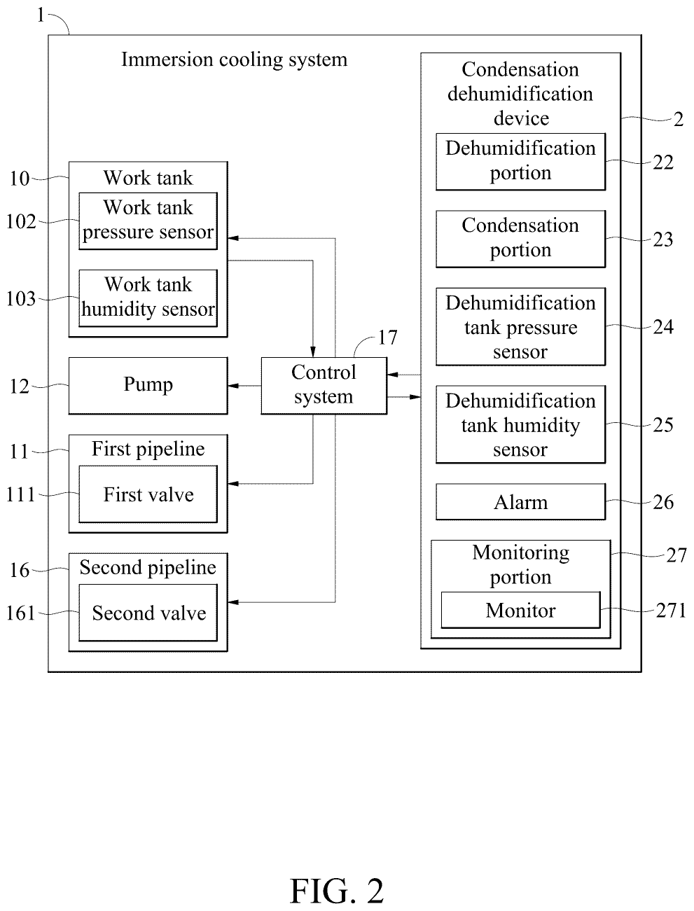

Please refer to FIG. 1 and FIG. 2. FIG. 1 illustrates a schematic perspective view of an immersion cooling system 1 according to some embodiments and FIG. 2 illustrates a schematic block diagram of a control system 17 of the immersion cooling system 1 shown in FIG. 1. In FIG. 1, an immersion cooling system 1 having a condensation dehumidification device 2 comprises a work tank 10, a pump 12, a first pipeline 11, the condensation dehumidification device 2, a second pipeline 16, and a control system 17 (as shown in FIG. 2). The work tank 10 is adapted to receive a working fluid (which will be described later). The work tank 10 comprises a vapor section V and a work tank humidity sensor 103. The vapor section V is for receiving a mixed vapor-phase fluid 105 (including a part of the working fluid (e.g., a vapor-phase working fluid) and moisture, which will be described later). The work tank humidity sensor 103 is for sensing a humidity of the vapor section V (which will be described later). The pump 12 has an inlet 120 and an outlet 121. The vapor section V and the inlet 120 are in communication with each other through the first pipeline 11. The first pipeline 11 comprises a first valve 111, wherein the vapor section V and the pump 12 are selectively in communication with each other or not in communication with each other in response to that the first valve 111 is actuated (which will be described later). The condensation dehumidification device 2 has a first end 201 and a second end 202, wherein the first end 201 is in communication with the outlet 121 (which will be described later). The second end 202 of the condensation dehumidification device 2 and the work tank 10 are in communication with each other through the second pipeline 16. The second pipeline 16 comprises a second valve 161, wherein the condensation dehumidification device 2 and the work tank 10 are selectively in communication with each other or not in communication with each other in response to that the second valve 161 is actuated (which will be described later). The control system 17 (as shown in FIG. 2) is for controlling the first valve 111 to be in communication with the vapor section V and the pump 12 and actuating the pump 12 in response to that the humidity of the vapor section V is greater than a preset humidity (which will be described later). Hence, the control system 17 determines whether or not to dehumidify the vapor section V through monitoring the humidity of the vapor section V; the mixed vapor-phase fluid 105 of the vapor section V would be instantly transported to the condensation dehumidification device 2 in response to that the control system 17 determines to dehumidify the vapor section V. Accordingly, the humidity of the vapor section V can be prevented from being unduly high, and thus the cooling performance of the work tank 10 can be also prevented from being affected by the unduly high humidity of the vapor section V. Further, since the mixed vapor-phase fluid 105 is directly transported to the condensation dehumidification device 2 outside of the work tank 10, the work tank 10 can be avoided being repeatedly opened, so that the vapor-phase working fluid in the work tank 10 can also be prevented from being excessively volatilized and escaping.

Please still refer to FIG. 1. In some embodiments, the work tank 10 comprises a work tank body 100 adapted to receive the working fluid and a component to be cooled 101. The working fluid (or referred to as the heat exchange fluid) is a non-conductive fluid. Under normal circumstances (i.e., at a temperature below the boiling point of the working fluid), the working fluid is a liquid (hereinafter, referred to as a liquid-phase working fluid 104). Further, since the boiling point of the working fluid is less than or substantially equal to the temperature of the component to be cooled 101, when the component to be cooled 101 is immersed in the liquid-phase working fluid 104, the liquid-phase working fluid 104 would absorb the heat from the component to be cooled 101 and thus the temperature of the liquid-phase working fluid 104 quickly reaches its critical boiling point. Therefore, the liquid-phase working fluid 104 is further evaporated as the vapor-phase working fluid. In FIG. 1, the vapor section V is adapted to receive the mixed vapor-phase fluid 105 (including the vapor-phase working fluid and the moisture), and a liquid section L is adapted to receive the liquid-phase working fluid 104 and the component to be cooled 101. The component to be cooled 101 can be any component with a temperature greater than the temperature of the working fluid, which is not particularly limited. For example, the number of the component(s) to be cooled 101 is one or more than one. For another example, the component to be cooled 101 can be a single rack-mounted server element or a cabinet-mounted server system including multiple rack-mounted server elements.

Please refer to FIG. 1 and FIG. 2. In some embodiments, the work tank 10 further comprises a work tank pressure sensor 102 for sensing a pressure of the work tank 10 and transmitting the pressure of the work tank 10 back to the control system 17. In FIG. 1, the work tank pressure sensor 102 can be such as a pressure gauge in communication with the work tank body 100 to sense the internal pressure of the work tank body 100. The work tank pressure sensor 102 transmits the obtained pressure back to the control system 17 (as shown in FIG. 2) to have the obtained pressure of the work tank body 100 received by the control system 17, where the pressure of the work tank body 100 can be further served as a criterion for whether the vapor section V should be in communication with the condensation dehumidification device 2 or not. Since the pressure of the work tank 10 that is transmitted back from the work tank pressure sensor 102 is directly related to a dew point (at which a vapor is condensed into a liquid), the pressure of the work tank 10 can be served as a criterion for whether the vapor suction procedure of the work tank 10 should be conducted or terminated or not. For example, an upper threshold value of pressure (e.g., 1.0 atm) or an upper threshold interval of pressure (e.g., 1.0-1.02 atm) and a lower threshold value of pressure (e.g., 0.90 atm) or a lower threshold interval of pressure (e.g., 0.90-0.92 atm) can be set by the control system 17. Therefore, in response to that the pressure (e.g., 1.03-1.07 atm) of the work tank 10 transmitted back by the work tank pressure sensor 102 is greater than or equal to the upper threshold value of pressure or the upper threshold interval of pressure, the control system 17 would instantly determine to conduct the vapor suction procedure of the work tank 10. In contrast, in response to that the pressure (e.g., 0.88 atm) of the work tank 10 transmitted back by the work tank pressure sensor 102 is less than or equal to the lower threshold value of pressure or the lower threshold interval of pressure, the control system 17 would instantly determine to terminate the vapor suction procedure of the work tank 10. The upper threshold value of pressure, the upper threshold interval of pressure, the lower threshold value of pressure, and/or the lower threshold interval of pressure can be adjusted based on actual demands, which is not particularly limited herein. In some embodiments, the lower threshold value of pressure and/or the lower threshold interval of pressure is a negative pressure that is less than or equal to 1 atm (e.g., 0.90-0.99 atm).

Please still refer to FIG. 1 and FIG. 2. In some embodiments, the work tank 10 further comprises a work tank humidity sensor 103 for sensing a humidity of the work tank 10 and transmitting the humidity of the work tank 10 back to the control system 17. In FIG. 1, the work tank humidity sensor 103 can be such as a hygrometer for measuring the moisture content in the environment and the hygrometer is in communication with the work tank body 100 to sense the internal humidity of the work tank body 100. The work tank humidity sensor 103 transmits the obtained humidity back to the control system 17 (as shown in FIG. 2) to have the humidity of the work tank body 100 received by the control system 17, where the obtained humidity of the work tank body 100 can be further served as a criterion for whether the vapor section V should be in communication with the condensation dehumidification device 2 or not. That is, in some embodiments, the obtained humidity of the work tank 10 transmitted back from the work tank humidity sensor 103 can be served as a criterion for whether the vapor suction procedure of the work tank 10 should be conducted or terminated or not. For example, a preset humidity (for example, an upper humidity threshold value (e.g., 80%) or an upper humidity threshold interval (e.g., 80-85%)) can be set by the control system 17. Therefore, in response to that the humidity (e.g., 86%) of the work tank 10 transmitted back by the work tank humidity sensor 103 is greater than or equal to the upper threshold value of humidity or the upper threshold interval of humidity, the control system 17 would instantly determine to conduct the vapor suction procedure of the work tank 10. Meanwhile, according to some embodiments, a lower humidity threshold value (e.g., 50%) or a lower humidity threshold interval (e.g., 50-55%) can be further set by the control system 17. Therefore, in response to that the humidity (e.g., 45%) of the work tank 10 transmitted back by the work tank humidity sensor 103 is less than or equal to the lower threshold value of humidity or the lower threshold interval of humidity, the control system 17 would instantly determine to terminate the vapor suction procedure of the work tank 10. The upper threshold value of humidity, the upper threshold interval of humidity, the lower threshold value of humidity, and/or the lower threshold interval of humidity can be adjusted based on actual demands, which is not particularly limited herein.

Please still refer to FIG. 1 and FIG. 2. In some embodiments, the work tank 10 comprises a work tank pressure sensor 102 and a work tank humidity sensor 103. For example, in FIG. 1 and FIG. 2, an upper threshold value of humidity (e.g., 80%) or an upper threshold interval of humidity (e.g., 80-85%) and a lower threshold value of pressure (e.g., 0.90 atm) or a lower threshold interval of pressure (e.g., 0.90-0.92 atm) can be set by the control system 17. Therefore, in response to that the humidity (e.g., 86%) of the work tank 10 transmitted back by the work tank humidity sensor 103 is greater than or equal to the upper threshold value of humidity or the upper threshold interval of humidity, the control system 17 would instantly determine to conduct the vapor suction procedure of the work tank 10. In contrast, in response to that the pressure (e.g., 0.88 atm) of the work tank 10 transmitted back by the work tank pressure sensor 102 is less than or equal to the lower threshold value of pressure or the lower threshold interval of pressure, the control system 17 would instantly determine to terminate the vapor suction procedure of the work tank 10. The upper threshold value of humidity, the upper threshold interval of humidity, the lower threshold value of pressure, and/or the lower threshold interval of pressure can be adjusted based on actual demands, which is not particularly limited herein.

Alternatively, for example, in FIG. 1 and FIG. 2, an upper threshold value of humidity (or an upper threshold interval of humidity) and an upper threshold value of pressure (or an upper threshold interval of pressure) as well as a lower threshold value of humidity (or a lower threshold interval of humidity) and a lower threshold value of pressure (or a lower threshold interval of pressure) can be all set by the control system 17 in the meanwhile. Therefore, the control system 17 can be set to determine to conduct the vapor suction procedure of the work tank 10 in response to that at least one of the conditions (including the condition that the humidity is greater than or equal to the upper threshold value of humidity (or the upper threshold interval of humidity) and the condition that the pressure is greater than or equal to the upper threshold value of pressure (or the upper threshold interval of pressure)) is met. In contrast, the control system 17 can be set to determine to terminate the vapor suction procedure of the work tank 10 in response to that at least one of the conditions (including the condition that the humidity is less than or equal to the lower threshold value of humidity (or the lower threshold interval of humidity) and the condition that the pressure is less than or equal to the lower threshold value of pressure (or the lower threshold interval of pressure)) is met. The upper threshold value of humidity, the upper threshold interval of humidity, the lower threshold value of pressure, and/or the lower threshold interval of pressure can be adjusted based on actual demands, which is not particularly limited herein. Accordingly, through setting the control system 17 to monitor the pressure and humidity of the work tank 10, the vapor suction procedure could be conducted in response to that at least one of the upper pressure threshold and the upper humidity threshold is met and terminated in response to that at least one of the lower pressure threshold and the lower humidity threshold is met, respectively. Therefore, according to some embodiments, problems such as that the work tank 10 cannot be monitored or even the vapor suction procedure cannot be properly conducted upon any one of the work tank pressure sensor 102 and the work tank humidity sensor 103 fails to be in operation properly can be avoided.

Please still refer to FIG. 1 and FIG. 2. In some embodiments, the first pipeline 11 comprises a first connecting pipe 110 and a first valve 111, wherein the vapor section V and the inlet 120 of the pump 12 are in communication with each other through the first connecting pipe 110, and the first valve 111 is between the vapor section V and the inlet 120. The vapor section V and the pump 12 are selectively in communication with each other or not in communication with each other in response to that the first valve 111 is actuated. In response to that the vapor section V and the pump 12 are communicated with each other through the first valve 111, due to the high pressure of the vapor section V and the driving of the pump 12, the vapor (including the vapor-phase working fluid and the moisture) in the vapor section V would be further transported to the interior of the condensation dehumidification device 2. Hence, the pump 12 can adjust the pressure of the work tank 10, for example, to a negative pressure that is less than or equal to 1 atm. In some embodiments, the first valve 111 is an electronic valve communicationally connected to the control system 17 (as shown in FIG. 2), and the control system 17 is for actuating the communication status of the first valve 111. In some embodiments, the first valve 111 is a non-return valve (or referred to as a check valve), which only allows the vapor to flow in one flowing direction (for example, a direction from the vapor section V to the inlet 120) but prevents the vapor from flowing in a direction opposite to the flowing direction (for example, a direction from the inlet 120 to the vapor section V), so that the vapor in the first connecting pipe 110 can be prevented from flowing back to the vapor section V again. Further, in some embodiments, the temperature of the first connecting pipe 110 (and even the temperature of the first valve 111) is greater than or equal to the boiling point or the dew point of the vapor (for example, greater than or equal to the boiling point or the dew point of the moisture, and also greater than the boiling point or the dew point of the working fluid) to prevent the vapor from being condensed into liquid in the transportation to the pump 12.

Please still refer to FIG. 1 and FIG. 2. In some embodiments, the immersion cooling system 1 further comprises a third pipeline 15, and the pump 12 and the condensation dehumidification device 2 are in communication with each other through the third pipeline 15. For example, in FIG. 1, the third pipeline 15 comprises a third connecting pipe 150, and the outlet 121 of the pump 12 and the first end 201 are in communication with each other through the third connecting pipe 150. In some embodiments, the third pipeline 15 further comprises a third valve (not illustrated), and the third valve is between the pump 12 and the condensation dehumidification device 2. The pump 12 and the condensation dehumidification device 2 are selectively in communication with each other or not in communication with each other in response to that the third valve is actuated. In some embodiments, the third valve is an electronic valve communicationally connected to the control system 17 (as shown in FIG. 2) and/or a non-return valve, whose implementations can be referred to the above description and thus are not further described herein. Further, in some embodiments, the temperature of the third connecting pipe 150 (and even the temperature of the third valve) is greater than or equal to the boiling point or the dew point of the vapor (for example, greater than or equal to the boiling point or the dew point of the moisture, and also greater than the boiling point or the dew point of the working fluid) to prevent the vapor from being condensed into liquid in the transportation to the condensation dehumidification device 2.

Please still refer to FIG. 1. The pump 12 has an inlet 120 and an outlet 121. The pump 12 can be various devices that can increase the pressure of the fluid so that the fluid has a greater propulsion force, and thus implementation of the pump 12 is not particularly limited here. Hence, the mixed vapor-phase fluid 105 can be pumped from the inlet 120 of the pump 12 to the outlet 121 of the pump 12 and further enter the interior of the condensation dehumidification device 2 through the first end 201. Moreover, in some embodiments, the temperature of the pump 12 is greater than or equal to the boiling point or the dew point of the vapor (for example, greater than or equal to the boiling point or the dew point of the moisture, and also greater than the boiling point or the dew point of the working fluid) to prevent the vapor from being condensed into liquid in the transportation of the pump 12.

Please still refer to FIG. 1. In some embodiments, a position of the first end 201 of the condensation dehumidification device 2 is higher than a position of the second end 202. In FIG. 1, the condensation dehumidification device 2 comprises a dehumidification tank 20, a first end 201, and a second end 202. The first end 201 and the second end 202 are both on the dehumidification tank 20, so that the interior and the exterior of the dehumidification tank 20 are in communication with each other through the first end 201 and the second end 202, and the position of the first end 201 is higher than the position of the second end 202. Therefore, if the vapor-phase working fluid once entering from the first end 201 is condensed into a liquid-phase working fluid (i.e., a condensed fluid 210), the condensed fluid 210 can be collected at or near the second end 202 by gravity. Accordingly, through adjusting the configurations of the first end 201 and the second end 202, the condensed fluid 210 can be further collected.

Please still refer to FIG. 1. In some embodiments, the condensation dehumidification device 2 further comprises a collecting portion 21 at the second end 202. In FIG. 1, the collecting portion 21 is at the bottom (i.e., the direction of gravity, such as the -Z direction in FIG. 1) of the dehumidification tank 20 and in communication with the work tank 10. In some embodiments, the collecting portion 21 is a receiving space with a larger opening and tapered toward the direction of gravity to form a tapered structure (in this embodiment, as shown, the cross-section of the collecting portion 21 is similar to an inverted triangle), and the second end 202 is at the bottom of the tapered structure. Accordingly, through the collecting portion 21, the condensed fluid 210 can be further collected at a specific position. In some embodiments, the second end 202 at the collecting portion 21 is in communication with the work tank 10, so that through adjusting the communication between the second end 202 and the work tank 10, the condensed fluid 210 collected at the collecting portion 21 can flow back to the work tank 10 to be further reused.

Please still refer to FIG. 1. In some embodiments, the condensation dehumidification device 2 can be divided into a first section S1 and a second section S2 by a liquid-vapor line S. In FIG. 1, according to the liquid-vapor line S (e.g., the position of the first end 201), the condensation dehumidification device 2 can be roughly divided into the first section S1 and the second section S2. For example, a part of the condensation dehumidification device 2 higher than the position of the first end 201 is referred to as the first section S1; and the other part lower than the position of the first end 201 (even including the collecting portion 21) is referred to as the second section S2. In some embodiments, the specific gravity of the vapor-phase working fluid is substantially greater than the specific gravity of moisture. Hence, once the moisture with a less specific gravity enters the dehumidification tank 20, the moisture would first flow toward the upper part of the liquid-vapor line S and then be collected at the first section S1; in contrast, the vapor-phase working fluid with a greater specific gravity would be collected between the first section S1 and the second section S2, or even flow to the lower part of the liquid-vapor line S and then be collected at the top of the second section S2; the condensed fluid 210 would be formed and collected at the bottom of the second section S2. It should be noted that although the first section S1 and the second section S2 can be roughly divided, for example, based on the position of the first end 201, it should also be appreciated that the liquid-vapor line S between the first section S1 and the second section S2 is not a fixed boundary, and the liquid-vapor line S would be varied according to the relative ratio of an amount of the moisture over an amount of the vapor-phase working fluid inside the condensation dehumidification device 2. For example, in response to that the amount of the moisture with a less specific gravity is larger, the liquid-vapor line S would be shifted toward the vapor-phase working fluid with a greater specific gravity in a direction of gravity (i.e., the −Z direction in FIG. 1), so that the bottom of the first section S1 might be substantially lower than the position of the first end 201, for example. In contrast, in response to that the amount of the vapor-phase working fluid with a greater specific gravity is larger, the liquid-vapor line S would be shifted toward the moisture with a less specific gravity in the opposite direction of gravity (i.e., the +Z direction in FIG. 1), so that the bottom of the first section S1 might be substantially higher than the position of the first end 201, for example.

According to the physical characteristics of the moisture, the vapor-phase working fluid, and the condensed fluid 210 (such as the liquid-vapor line S, the first section S1, and the second section S2), different collection ways can be provided at corresponding collecting positions so as to collect the moisture, the vapor-phase working fluid, and the condensed fluid 210, respectively.

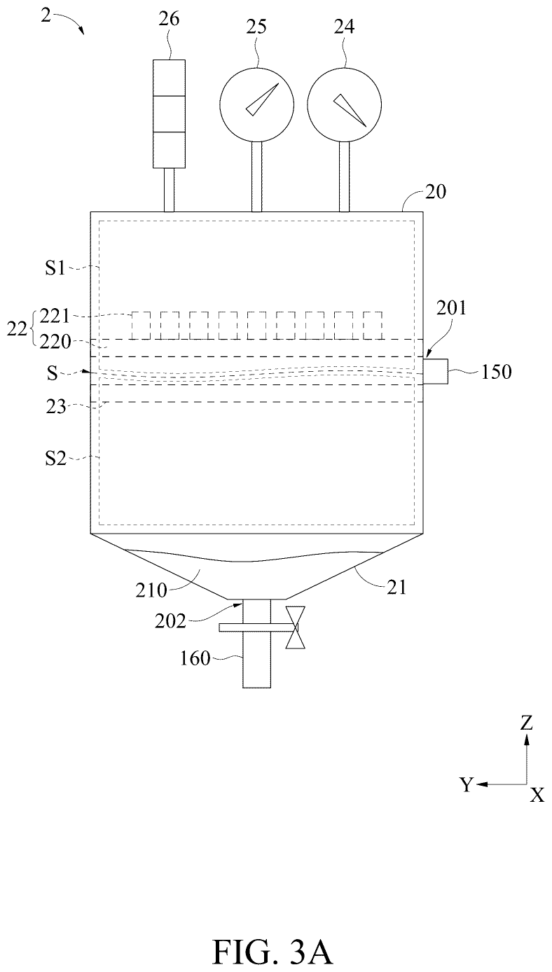

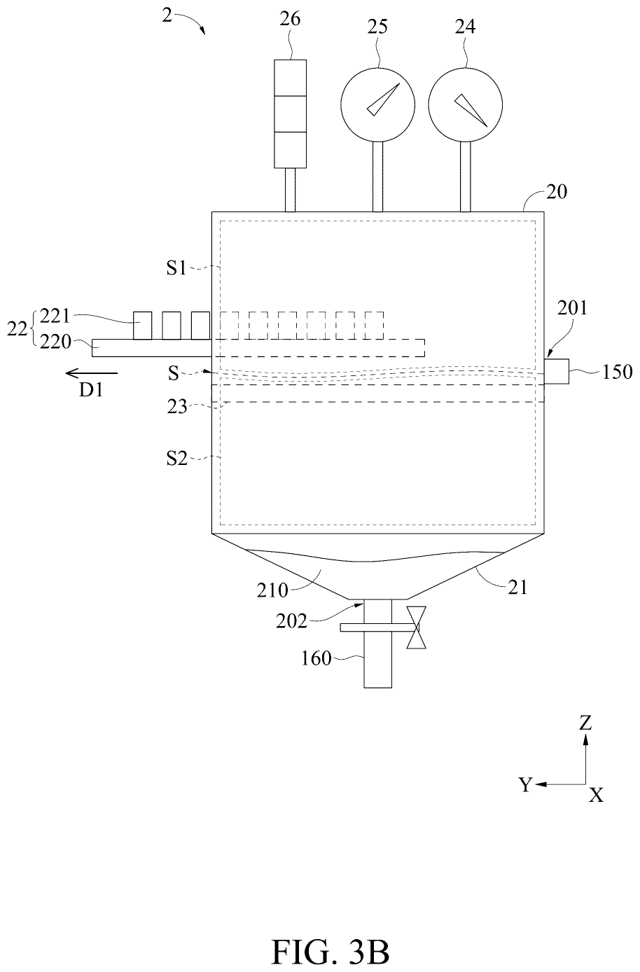

For example, please refer to FIG. 3A and FIG. 3B. FIG. 3A and FIG. 3B respectively illustrate schematic working diagrams in a first view (i.e., the YZ plane) of a condensation dehumidification device 2 of the immersion cooling system 1 shown in FIG. 1. In FIG. 3A and FIG. 3B, the condensation dehumidification device 2 comprises a dehumidification portion 22 for removing the moisture. In some embodiments, the position of the dehumidification portion 22 is correspondingly at the first section S1 and can be adjusted based on actual demands. For example, the dehumidification portion 22 is at the bottom of the first section S1 (that is, the first section S1 adjacent to the liquid-vapor line S). For another example, the position of the dehumidification portion 22 is higher than the position of the first end 201 of the condensation dehumidification device 2. Therefore, upon entering the dehumidification tank 20, a large amount of the moisture would flow upward due to the less specific gravity of the moisture and contact with the dehumidification portion 22 to be then removed, so that further reaction(s) between the moisture and the vapor-phase working fluid can be avoided. The dehumidification portion 22 can be, for example, a desiccant; preferably, in some embodiments, a desiccant for absorbing or adsorbing moisture, such as a chemical desiccant (e.g., calcium sulfate and calcium chloride) and a physical desiccant (e.g., silica gel and alumina). Accordingly, through the dehumidification portion 22, the moisture inside the condensation dehumidification device 2 (for example, the moisture collected at the first section S1) can be removed and thus the moisture can be further prevented from being condensed and flowing back to the work tank 10. In addition, through removal of the moisture in the work tank 10 and the condensation dehumidification device 2, component(s) inside the work tank 10 and the condensation dehumidification device 2 can be also prevented from being rusted or corroded due to the moisture, thereby extending the service life of the component(s).

In some embodiments, in FIG. 3A and FIG. 3B, the dehumidification portion 22 comprises a dehumidification base 220 and one or more dehumidification packs 221. The dehumidification base 220 is movably or fixedly in the dehumidification tank 20 (for example, at the bottom of the first section S1). In some embodiments, the dehumidification base 220 has a net structure, and the net structure allows the moisture to flow freely and be further collected at a position above the dehumidification base 220. Each of the dehumidification packs 221 is on the dehumidification base 220 and movably or fixedly in the dehumidification tank 20 based on the configuration of the dehumidification base 220. In FIG. 3A and FIG. 3B, the dehumidification base 220 can be a dehumidification base 220 capable of moving back and forth in a first direction D1. For example, the dehumidification base 220 has one or more slide rails, and the dehumidification tank 20 has component(s) corresponding to the slide rails; therefore, the dehumidification packs 221 can be replaced by moving the dehumidification base 220 back and forth in the first direction D1. Each of the dehumidification packs 221 can have one or more desiccants, and each of the dehumidification packs 221 and/or desiccants thereof can be arranged according to different demands. Accordingly, through various dehumidification packs 221 and/or desiccants thereof, various moisture removal performances in different spatial positions can be provided by the dehumidification portion 22. For example, at the position adjacent to the first end 201 (that is, the first section S1 adjacent to the liquid-vapor line S), the dehumidification portion 22 is arranged to have a relatively larger amount of the dehumidification packs 221 with a better moisture removal performance. Hence, upon entering the dehumidification tank 20, a large amount of the moisture would be instantly removed by the dehumidification portion 22, so that further reaction(s) between the moisture and the vapor-phase working fluid can be avoided.

For another example, in FIG. 3A and FIG. 3B, the condensation dehumidification device 2 comprises a condensation portion 23 for condensing the vapor-phase working fluid. The position of the condensation portion 23 is arranged based on the position of the dehumidification portion 22 and the first end 201 to condense the vapor-phase working fluid into the condensed fluid 210 more efficiently. In some embodiments, the position of the condensation portion 23 is arranged based on the collection position of the moisture (for example, the condensation portion 23 is away from the collection position of the moisture) to prevent from condensing the moisture. The condensation portion 23 can be various heat exchange devices capable of cooling, which is not particularly limited herein; for example, a fluid with a temperature less than or equal to the boiling point and the dew point of the working fluid can be applied to the interior of the condensation portion 23, so that the vapor-phase working fluid can be condensed into the condensed fluid 210 upon contacting the outer surface of the condensation portion 23 or being adjacent to the condensation portion 23. In some embodiments, the position of the condensation portion 23 is at or lower than the bottom of the first section S1. For example, in FIG. 3A and FIG. 3B, the position of the condensation portion 23 is lower than the position of the first end 201 and higher than the position of the second end 202 (e.g., the second section S2 adjacent to the liquid-vapor line S) to condense the vapor-phase working fluid into the condensed fluid 210 at the collection position of the vapor-phase working fluid more efficiently.

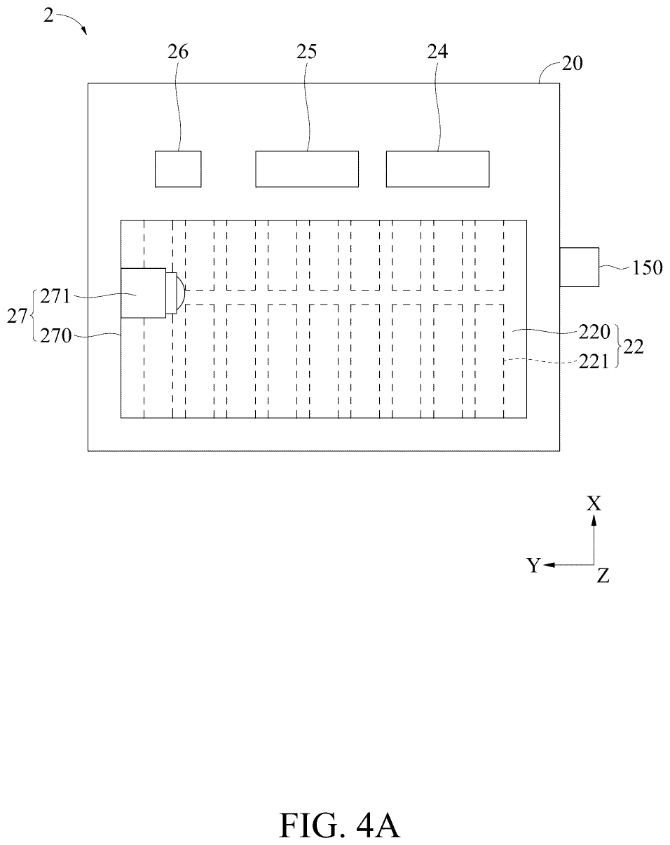

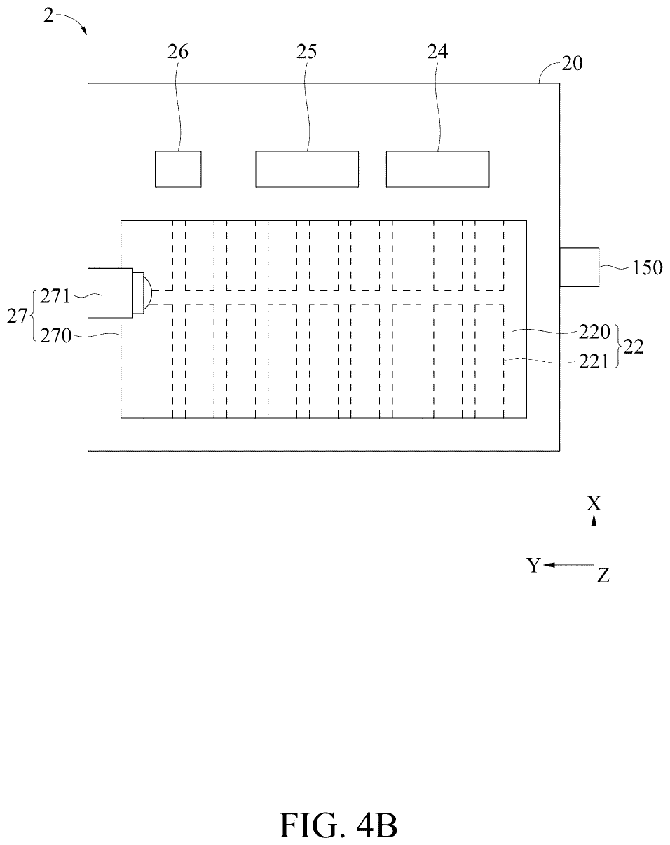

Please refer to FIG. 4A and FIG. 4B. FIG. 4A and FIG. 4B respectively illustrate schematic working diagrams in a second view (i.e., the XY plane) of a condensation dehumidification device 2 of the immersion cooling system 1 shown in FIG. 1. In some embodiments, the condensation dehumidification device 2 further comprises a monitoring portion 27 adjacent to the dehumidification portion 22 to monitor the use of the dehumidification portion 22.

In FIG. 4A and FIG. 4B, the monitoring portion 27 according to some embodiments is a light-transmissive element 270 adjacent to the dehumidification portion 22. The light-transmissive element 270 can have naked eyes and/or a monitor 271 (which will be described later) updated by a status of the dehumidification portion 22 (for example, whether the dehumidification portion 22 is wet and needs to be replaced or not). The light-transmissive element 270 can be made of various light-transmissive materials, which is not particularly limited herein; for example, the light-transmissive element 270 can be transparent glass.

In FIG. 4A and FIG. 4B, the monitoring portion 27 according to some embodiments is a monitor 271 adjacent to the dehumidification portion 22. For example, in FIG. 4A and FIG. 4B, the monitor 271 is adjacent to the light-transmissive element 270. The monitor 271 can obtain the status of the dehumidification portion 22 (for example, whether the dehumidification portion 22 is wet and needs to be replaced or not). The monitor 271 can be arranged inside the dehumidification tank 20 (as shown in FIG. 4A) or can be arranged outside the dehumidification tank 20 (as shown in FIG. 4B), which is not particularly limited herein. The monitor 271 can be various devices capable of capturing pictures or images, which is not particularly limited herein; for example, the monitor 271 is a video recorder, a camera, or a combination thereof. Further, the monitor 271 according to some embodiments can be communicationally connected to the control system 17 (as shown in FIG. 2), and the monitor 271 is for transmitting the status of the dehumidification portion 22 back to the control system 17 to monitor the use of the dehumidification portion 22.

Please refer again to FIG. 1 and FIG. 2. In some embodiments, the condensation dehumidification device 2 further comprises a dehumidification tank humidity sensor 25 for sensing a humidity of the condensation dehumidification device 2 and transmitting the humidity of the condensation dehumidification device 2 back to the control system 17 (as shown in FIG. 2). In FIG. 1, the dehumidification tank humidity sensor 25 can be such as a hygrometer for measuring the moisture content in the environment and the hygrometer is in communication with the dehumidification tank 20 to sense the internal humidity of the dehumidification tank 20. The dehumidification tank humidity sensor 25 transmits the obtained humidity back to the control system 17 (as shown in FIG. 2) to obtain the humidity of the dehumidification tank 20 received by the control system 17, where the obtained humidity of the dehumidification tank 20 can be further served as a criterion for whether the condensation dehumidification device 2 is still in normal operation and/or whether the dehumidification portion 22 should be replaced or not.

Please still refer to FIG. 1 and FIG. 2. In some embodiments, the condensation dehumidification device 2 further comprises a dehumidification tank pressure sensor 24 for sensing a pressure of the condensation dehumidification device 2 and transmitting the pressure of the condensation dehumidification device 2 back to the control system 17 (as shown in FIG. 2). In FIG. 1, the dehumidification tank pressure sensor 24 can be such as a pressure gauge in communication with the dehumidification tank 20 to sense the internal pressure of the dehumidification tank 20. The dehumidification tank pressure sensor 24 transmits the obtained pressure back to the control system 17 (as shown in FIG. 2) to obtain the pressure of the dehumidification tank 20 received by the control system 17, where the obtained pressure of the dehumidification tank 20 can be further served as a criterion for whether the condensation dehumidification device 2 is still in normal operation and/or whether the dehumidification portion 22 should be replaced or not.

In some embodiments, the condensation dehumidification device 2 further comprises a dehumidification tank temperature sensor (not illustrated) for sensing a temperature of the condensation dehumidification device 2 and transmitting the temperature of the condensation dehumidification device 2 back to the control system 17 (as shown in FIG. 2). The dehumidification tank temperature sensor can be such as a thermometer in communication with the dehumidification tank 20 to sense the internal temperature of the dehumidification tank 20. The dehumidification tank temperature sensor transmits the obtained temperature back to the control system 17 (as shown in FIG. 2) to obtain the temperature of the dehumidification tank 20 received by the control system 17, where the obtained temperature of the dehumidification tank 20 can be further served as a criterion for whether the condensation dehumidification device 2 is still in normal operation or not.

Please still refer to FIG. 1 and FIG. 2. In some embodiments, the condensation dehumidification device 2 further comprises an alarm 26 communicationally connected to the control system 17 (as shown in FIG. 2). The alarm 26 can be various devices capable of attracting attention, which is not particularly limited herein; for example, the alarm 26 can be a device that can alert a sound (such as buzzing), produce a visual effect (such as flashing light, color changing), or a combination thereof. In response to that the humidity of the condensation dehumidification device 2 is greater than a humidity threshold, the control system 17 controls the alarm 26 to alert a warning to warn that the humidity of the condensation dehumidification device 2 is abnormal. In addition, in some embodiments, in response to that the pressure of the condensation dehumidification device 2 is greater than a pressure threshold, the control system 17 controls the alarm 26 to alert a warning to warn that the pressure of the condensation dehumidification device 2 is abnormal. Moreover, in some embodiments, in response to that the temperature of the condensation dehumidification device 2 is greater than a temperature threshold, the control system 17 controls the alarm 26 to alert a warning to warn that the temperature of the condensation dehumidification device 2 is abnormal.

In some embodiments, the condensation dehumidification device 2 further comprises a pressure relief valve (not illustrated) in communication with the interior and the exterior of the dehumidification tank 20 so as to balance the pressure difference inside and outside the dehumidification tank 20, where the pressure difference is caused by condensation of the vapor-phase working fluid and formation of the condensed fluid 210.

Pleaser still refer to FIG. 1 and FIG. 2. In some embodiments, the second pipeline 16 comprises a second connecting pipe 160 and a second valve 161, wherein the second end 202 and the work tank 10 are in communication with each other through the second connecting pipe 160, and the second valve 161 is between the second end 202 and the work tank 10. The condensation dehumidification device 2 and the work tank 10 are selectively in communication with each other or not in communication with each other in response to that the second valve 161 is actuated. The second valve 161 can be an electronic valve communicationally connected to the control system 17 (as shown in FIG. 2) and/or a non-return valve, whose implementations can be referred to the above description and thus are not further described herein. Further, in some embodiments, the temperature of the second connecting pipe 160 (and even the temperature of the second valve 161) is less than or equal to the boiling point or the dew point of the condensed fluid 210 (for example, less than or equal to the boiling point or the dew point of the working fluid) to prevent the condensed fluid 210 from being evaporated into the vapor-phase working fluid in the transportation to the work tank 10.

Please still refer to FIG. 1 and FIG. 2. In some embodiments, the second pipeline 16 further comprises a filtration portion 162 for filtrating the condensed fluid 210 from the condensation dehumidification device 2 and even for removing the moisture that might contain in the condensed fluid 210. For example, the second connecting pipe 160 of the second pipeline 16 is adapted to be in communication with the filtration portion 162. The filtration portion 162 can be between the second end 202 and the second valve 161, or between the second valve 161 and the work tank 10 (as shown in FIG. 1), which is not particularly limited herein. The filtration portion 162 can be various devices with functions of filtrating impurities and/or removing moisture, which is not particularly limited herein; for example, the filtration portion 162 is aluminum oxide, graphite, or a combination thereof. Accordingly, through the filtration portion 162, before the condensed fluid 210 flows back to the work tank 10, the condensed fluid 210 can be first filtrated to prevent from containing impurities, so that the contamination or damage of the work tank 10 and the component to be cooled 101 caused by the impurities can be avoided. Moreover, before the condensed fluid 210 flows back to the work tank 10, the moisture that contains in the condensed fluid 210 can be also removed by the filtration portion 162, thereby preventing the condensed fluid 210 with the moisture from flowing back to the work tank 10.

Please refer to FIG. 2. In some embodiments, the control system 17 is communicationally connected to the work tank 10 (including the work tank pressure sensor 102 and the work tank humidity sensor 103), the first pipeline 11 (including the first valve 111), the pump 12, the condensation dehumidification device 2 (including the dehumidification portion 22, the condensation portion 23, the dehumidification tank pressure sensor 24, the dehumidification tank humidity sensor 25, the alarm 26, and the monitoring portion 27 (including the monitor 271)), and the second pipeline 16 (including the second valve 161) to transmit one or more control commands to the above components, and even receive signals and/or status from the above components.

In some embodiments, the control system 17 receives the humidity (i.e., the humidity of the work tank 10) from the work tank humidity sensor 103 and/or the pressure (i.e., the pressure of the work tank 10) from the work tank pressure sensor 102 to determine whether the vapor suction procedure of the work tank 10 should be conducted or not. In response to that the control system 17 determines to conduct the vapor suction procedure of the work tank 10, the control system 17 further receives the humidity (i.e., the humidity of the condensation dehumidification device 2) transmitted from the dehumidification tank humidity sensor 25 and/or the status of the dehumidification portion 22 transmitted from the monitoring portion 27 to determine whether the dehumidification portion 22 should be replaced or not. In response to that the control system 17 determines that the humidity of the condensation dehumidification device 2 is unduly high (and/or the dehumidification portion 22 is saturated) and thus the dehumidification portion 22 should be replaced, the first valve 111 would be actuated to be closed by the control system 17 to have the vapor section V and the pump 12 not in communication with each other. Then, the control system 17 receives the pressure (i.e., the pressure of the condensation dehumidification device 2) transmitted from the dehumidification tank pressure sensor 24 to determine if the status is suitable for replacing the dehumidification portion 22 (for example, the pressure of the condensation dehumidification device 2 is less than the pressure threshold). Next, in response to that the status is determined as suitable for replacing the dehumidification portion 22, the dehumidification portion 22 is replaced manually or firstly the control system 17 actuates the components of the condensation dehumidification device 2 and then the dehumidification portion 22 is replaced. After the dehumidification portion 22 is replaced, signals are transmitted back to the control system 17, so that the control system 17 further determines whether the vapor suction procedure of the work tank 10 should be resumed or not (for example, to determine whether the humidity transmitted from the dehumidification tank humidity sensor 25 is less than the humidity threshold or not). In response to that the control system 17 determines to resume the vapor suction procedure of the work tank 10, the first valve 111 and the pump 12 are actuated to be opened by the control system 17 so as to have the vapor section V and the pump 12 in communication with each other. Meanwhile, the moisture and the vapor-phase working fluid inside the vapor section V will be pumped by the pump 12 to enter the condensation dehumidification device 2 through the first end 201 for further dehumidification of the moisture and condensation of the vapor-phase working fluid. After condensed, the condensed fluid 210 will be collected at the second end 202. The control system 17 receives the humidity (i.e., the humidity of the work tank 10) transmitted from the work tank humidity sensor 103 and/or the pressure (i.e., the pressure of the work tank 10) transmitted from the work tank pressure sensor 102 to determine whether the vapor suction procedure of the work tank 10 should be terminated or not. In response to that the control system 17 determines to terminate the vapor suction procedure of the work tank 10, the pump 12 is actuated to be closed by the control system 17 to terminate the vapor suction procedure. Accordingly, through the control system 17, the status of the work tank 10 can be automatically sensed and further used to determine whether the vapor suction procedure of the work tank 10 should be conducted or terminated or not. Therefore, the humidity (i.e., the moisture content) inside the work tank 10 can be ensured to be within a normal interval of humidity, and the work performance of the liquid-phase working fluid 104 on cooling the component to be cooled 101 can be prevented from being significantly affected.

In some embodiments, under normal circumstances, the second valve 161 is in a closed state. The second valve 161 can be actuated and opened by the control system 17 based on the amount of the condensed fluid 210 to further have the condensation dehumidification device 2 and the work tank 10 in communication with each other through the second valve 161. In response to that the control system 17 determines to open the second valve 161, the condensed fluid 210 inside the condensation dehumidification device 2 would enter the work tank 10 from the second end 202, thereby backfilling the reduction of the liquid-phase working fluid 104 due to its evaporation and volatilization.

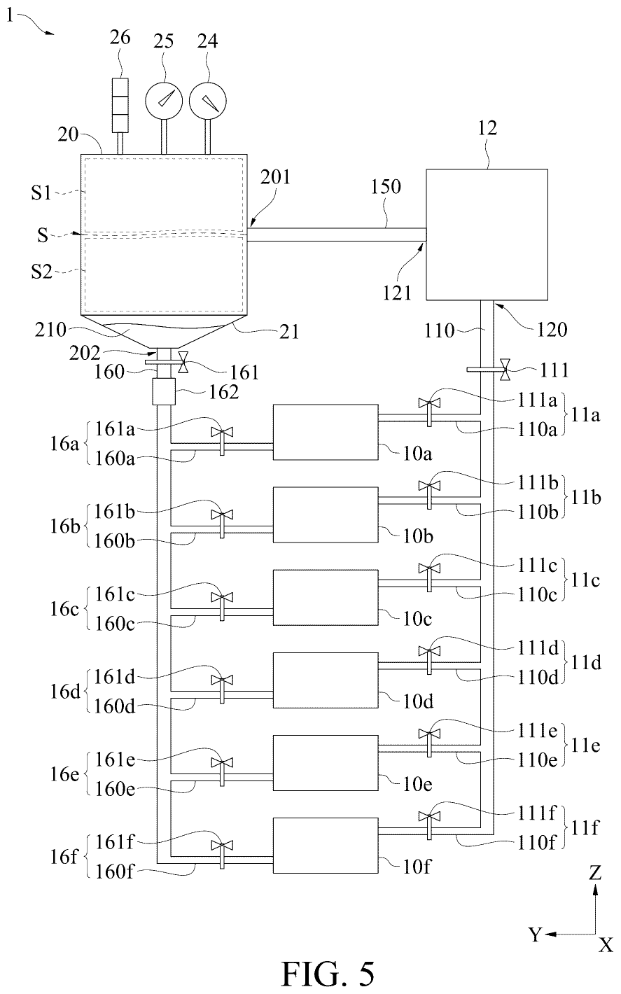

Please refer to FIG. 5. FIG. 5 illustrates a perspective view of an immersion cooling system 1 according to some embodiments. It should be noted that, for a clearer illustration, FIG. 5 only illustrates the work tanks 10a-10f and omits its detailed components, but it does not mean that the work tanks 10a-10f do not include these detailed components; instead, specific implementations of these detailed components can be referred to the above description and thus are not further described herein.

In FIG. 5, the immersion cooling system 1 according to some embodiments comprises a plurality of work tanks 10a-10f, wherein the first end 201 is in communication with each of the vapor sections V of the work tanks 10a-10f (each of the vapor sections V is not illustrated in FIG. 5, but shown in FIG. 1), and the second end 202 is in communication with each of the work tanks 10a-10f. Accordingly, through a central-control condensation dehumidification device 2, the work tanks 10a-10f can be dehumidified by the same one condensation dehumidification device 2, and the condensed fluid 210 can be further distributed back to each of the work tanks 10a-10f, so that the condensed fluid 210 (i.e., the liquid-phase working fluid 104) can be reused. The distribution of the condensed fluid 210 can be, for example, in proportion, in the order of dehumidification, or in accordance with the amounts of the liquid-phase working fluid 104 in each of the work tanks 10a-10f, which is not particularly limited herein. Furthermore, each of the work tanks 10a-10f can thus be prevented from being repeatedly opened, so that the vapor-phase working fluid in the work tanks 10a-10f can also be prevented from being excessively volatilized and escaping.

For example, in FIG. 5, the immersion cooling system 1 comprises six work tanks 10a-10f, a plurality of first sub-pipelines 11a-11f corresponding to each of the work tanks 10a-10f, and a plurality of second sub-pipelines 16a-16f corresponding to each of the work tanks 10a-10f. The first sub-pipelines 11a-11f comprise first sub-connecting pipes 110a-110f and first sub-valves 111a-111f, respectively. The vapor sections V of the work tanks 10a-10f (not illustrated in FIG. 5, but shown in FIG. 1) and the first connecting pipe 110 are in communication with each other through the first sub-connecting pipes 110a-110f, respectively. The first sub-valves 111a-111f are respectively between the work tanks 10a-10f and the first connecting pipe 110. In response to that the first sub-valves 111a-111f are respectively actuated, the work tanks 10a-10f and the first connecting pipe 110 are selectively in communication with each other or not in communication with each other through each of the first sub-valves 111a-111f. The second sub-pipelines 16a-16f comprise second sub-connecting pipes 160a-160f and second sub-valves 161a-161f, respectively. The work tanks 10a-10f and the second connecting pipe 160 are in communication with each other through the second sub-valves 161a-161f, respectively. The second sub-valves 161a-161f are respectively between the work tanks 10a-10f and the second connecting pipe 160. In response to that the second sub-valves 161a-161f are respectively actuated, the work tanks 10a-10f and the second connecting pipe 160 are selectively in communication with each other or not in communication with each other through each of the second sub-valves 161a-161f. The first valve 111, the second valve 161, the first sub-valves 111a-111f, and the second sub-valves 161a-161f are all communicationally connected to the control system 17 to receive one or more control commands from the control system 17 so as to conduct the vapor suction procedures with respect to any one or more of the work tanks 10a-10f according to the control commands, respectively.

For another example, in FIG. 5, the vapor suction procedure with respect to any one of the work tanks 10a-10f can be controlled by the control system 17. For example, the preset humidity of the vapor section V is set as 80% by the control system 17; the obtained humidity corresponding to the work tanks 10a-10f is respectively 85%, 82%, 80%, 60%, 75%, and 45%, for example, so there are only three work tanks 10a-10c with humidity (85%, 82%, and 80%) greater than or equal to the preset humidity (80%). Hence, only the three work tanks 10a-10c are further selected for the vapor suction procedure and the dehumidification procedure by the control system 17. The humidity greater than or equal to the preset humidity is rearranged from high to low in order by the control system 17, and the work tank 10a with the highest humidity (85%) is prioritized for the vapor suction procedure. The control system 17 can be set to conduct the vapor suction procedure on only one work tank 10a at the same time, while the other work tanks 10b-10c and their first sub-valves 111b-111c are kept not communicated. Accordingly, the pressure of each of the work tanks 10a-10c can be prevented from being in communication with each other, thereby preventing the pressure and humidity transmitted back to the control system 17 from being distorted, and even preventing the other work tanks 10b-10c from being contaminated or damaged. After the vapor suction procedure corresponding to the work tank 10a with the highest humidity is completed, the vapor suction procedure corresponding to the work tank 10b with the second highest humidity (82%) is then conducted, and finally the vapor suction procedure corresponding to the work tank 10c with the lowest humidity (80%) is conducted.

For another example, assumed that the humidity corresponding to the work tanks 10a-10f all reaches the preset humidity at which the corresponding vapor suction procedures and dehumidification procedures are needed, wherein each of the vapor suction procedures takes about 3 minutes, each of the dehumidification procedures (each including condensation procedure) takes about 7 minutes, and thus each of the overall procedures (including the vapor suction procedures and the dehumidification procedures) takes about 10 minutes. Therefore, the vapor suction procedures and the dehumidification procedures with respect to six work tanks 10a-10f can be respectively conducted by the condensation dehumidification device 2 in an hour. Accordingly, through the central-control condensation dehumidification device 2, a plurality of the work tanks 10a-10f can be efficiently dehumidified in a short time, and each of the work tanks 10a-10f can be prevented from being opened repeatedly, so that the vapor-phase working fluid in the work tanks 10a-10f can also be prevented from being excessively volatilized and escaping.

To sum up, in some embodiments, through a central-control condensation dehumidification device, one or more work tanks of an immersion cooling system can be efficiently dehumidified in a short time. Meanwhile, through the central-control condensation dehumidification device that is communicated from the exterior of the work tanks, the work tanks can be prevented from being opened repeatedly, so that the vapor-phase working fluid in the work tanks can also be prevented from being excessively volatilized and escaping, thereby preventing the cooling performance of working fluid in the work tanks from being affected. In addition, through the condensation dehumidification device and dehumidification portion thereof, moisture contained in the work tanks can be removed and prevented from flowing back to the work tanks again, so that the work tanks and component(s) inside the work tanks can be also prevented from being rusted or corroded due to the moisture, thereby preventing from shortening the service lives of the work tanks and/or the component(s).

What is claimed is:

1. An immersion cooling system having a condensation dehumidification device, the immersion cooling system comprising:
a work tank comprising:
a vapor section; and
a work tank humidity sensor for sensing a humidity of the vapor section;
a pump having an inlet and an outlet;
a first pipeline in communication with the vapor section and the inlet and comprising a first valve, wherein the vapor section and the pump are selectively in communication with each other or not in communication with each other in response to that the first valve is actuated;
the condensation dehumidification device having a first end and a second end, wherein the first end is in communication with the outlet;
a second pipeline in communication with the second end of the condensation dehumidification device and the work tank and comprising a second valve, wherein the condensation dehumidification device and the work tank are selectively in communication with each other or not in communication with each other in response to that the second valve is actuated; and
a control system for controlling the first valve to be in communication with the vapor section and the pump and actuating the pump in response to that the humidity of the vapor section is greater than a preset humidity.

2. The immersion cooling system according to claim 1, wherein the condensation dehumidification device comprises:
a dehumidification portion, wherein a position of the dehumidification portion is higher than a position of the first end; and
a condensation portion, wherein a position of the condensation portion is lower than the position of the first end and higher than a position of the second end.

3. The immersion cooling system according to claim 2, wherein the condensation dehumidification device further comprises a monitoring portion adjacent to the dehumidification portion.

4. The immersion cooling system according to claim 3, wherein the monitoring portion is a light-transmissive element for providing a status of the dehumidification portion.

5. The immersion cooling system according to claim 3, wherein the monitoring portion is a monitor for obtaining a status of the dehumidification portion and the monitor is communicationally connected to the control system to transmit the status back to the control system.

6. The immersion cooling system according to claim 3, wherein the monitoring portion comprises:
a light-transmissive element adjacent to the dehumidification portion; and
a monitor adjacent to the light-transmissive element, wherein the monitor is for obtaining a status of the dehumidification portion through the light-transmissive element and transmitting the status back to the control system.

7. The immersion cooling system according to claim 1, wherein a position of the first end is higher than a position of the second end.

8. The immersion cooling system according to claim 1, wherein the condensation dehumidification device further comprises a collecting portion at the second end of the condensation dehumidification device.

9. The immersion cooling system according to claim 1, wherein the condensation dehumidification device further comprises a dehumidification tank humidity sensor for sensing a humidity of the condensation dehumidification device and transmitting the humidity of the condensation dehumidification device back to the control system.

10. The immersion cooling system according to claim 9, wherein the condensation dehumidification device further comprises an alarm communicationally connected to the control system, wherein the control system is for controlling the alarm to alert a warning in response to that the humidity of the condensation dehumidification device is greater than a humidity threshold.

11. The immersion cooling system according to claim 1, wherein the work tank further comprises a work tank pressure sensor for sensing a pressure of the work tank and transmitting the pressure of the work tank back to the control system.

12. The immersion cooling system according to claim 11, wherein the pump is for adjusting the pressure of the work tank to a negative pressure in response to that the first valve is actuated and the vapor section and the pump are in communication with each other.

13. The immersion cooling system according to claim 12, wherein the negative pressure is less than 1 atm.

14. The immersion cooling system according to claim 1, wherein the condensation dehumidification device further comprises a dehumidification tank pressure sensor for sensing a pressure of the condensation dehumidification device and transmitting the pressure of the condensation dehumidification device back to the control system.

15. The immersion cooling system according to claim 1, further comprising a third pipeline in communication with the pump and the condensation dehumidification device.

16. The immersion cooling system according to claim 1, wherein the first valve is a non-return valve.

17. The immersion cooling system according to claim 1, wherein the second pipeline further comprises a filtration portion for filtrating a condensed fluid from the condensation dehumidification device.

18. The immersion cooling system according to claim 1, wherein the immersion cooling system comprises a plurality of the work tanks, the first end is in communication with the vapor section of each of the work tanks, and the second end is in communication with each of the work tanks.

19. A condensation dehumidification device for an immersion cooling system, the condensation dehumidification device having a first end and a second end, wherein the first end of the condensation dehumidification device is adapted to be selectively in communication with or not in communication with a vapor section of the immersion cooling system, the second end of the condensation dehumidification device is adapted to be selectively in communication with or not in communication with the immersion cooling system, and the condensation dehumidification device comprises:
a dehumidification portion, wherein a position of the dehumidification portion is higher than a position of the first end; and
a condensation portion, wherein a position of the condensation portion is lower than the position of the first end and higher than a position of the second end.

20. The condensation dehumidification device according to claim 19, wherein the first end is adapted to be in communication with a pump, the pump is adapted to be in communication with an end of a first pipeline, another end of the first pipeline is adapted to be in communication with the vapor section, the first pipeline comprises a first valve, and the pump and the vapor section are selectively in communication with each other or not in communication with each other in response to that the first valve is actuated.

21. The condensation dehumidification device according to claim 20, wherein the first valve is a non-return valve.

22. The condensation dehumidification device according to claim 19, wherein the first end is adapted to be in communication with an end of a third pipeline, another end of the third pipeline is adapted to be in communication with a pump, the pump is adapted to be in communication with an end of the first pipeline, another end of the first pipeline is adapted to be in communication with the vapor section, the first pipeline comprises a first valve, and the pump and the vapor section are selectively in communication with each other or not in communication with each other in response to that the first valve is actuated.

23. The condensation dehumidification device according to claim 19, wherein the second end of the condensation dehumidification device is adapted to be in communication with a second pipeline and the immersion cooling system, the second pipeline comprises a second valve, and the second end of the condensation dehumidification device and the immersion cooling system are selectively in communication with each other or not in communication with each other in response to that the second valve is actuated.

24. The condensation dehumidification device according to claim 23, wherein the second pipeline is adapted to be in communication with a filtration portion for filtrating a condensed fluid from the condensation dehumidification device.

25. The condensation dehumidification device according to claim 19, wherein a position of the first end is higher than a position of the second end.

26. The condensation dehumidification device according to claim 19, further comprising a collecting portion at the second end of the condensation dehumidification device.

27. The condensation dehumidification device according to claim 19, wherein the condensation dehumidification device is adapted to be communicationally connected to a control system and further comprises a dehumidification tank humidity sensor for sensing a humidity of the condensation dehumidification device and transmitting the humidity of the condensation dehumidification device back to the control system.

28. The condensation dehumidification device according to claim 27, further comprising an alarm communicationally connected to the control system, wherein the control system is for controlling the alarm to alert a warning in response to that the humidity of the condensation dehumidification device is greater than a humidity threshold.

29. The condensation dehumidification device according to claim 19, wherein the condensation dehumidification device is adapted to be communicationally connected to a control system and further comprises a dehumidification tank pressure sensor for sensing a pressure of the condensation dehumidification device and transmitting the pressure of the condensation dehumidification device back to the control system.

30. The condensation dehumidification device according to claim 19, further comprising a monitoring portion adjacent to the dehumidification portion.

31. The condensation dehumidification device according to claim 30, wherein the monitoring portion is a light-transmissive element for providing a status of the dehumidification portion.

32. The condensation dehumidification device according to claim 30, wherein the condensation dehumidification device is adapted to be communicationally connected to a control system, the monitoring portion is a monitor for obtaining a status of the dehumidification portion, and the monitor is communicationally connected to the control system to transmit the status back to the control system.

33. The condensation dehumidification device according to claim 30, wherein the condensation dehumidification device is adapted to be communicationally connected to a control system and the monitoring portion comprises:
a light-transmissive element adjacent to the dehumidification portion; and
a monitor adjacent to the light-transmissive element, wherein the monitor is for obtaining a status of the dehumidification portion through the light-transmissive element and transmitting the status back to the control system.
